(19) United States
(12) Patent Application Publication
(10) Pub. No.: US 2026/0320261 A1
(43) Pub. Date: Oct. 15, 2026

(54) ARTIFICIAL INTELLIGENCE TECHNIQUES FOR RENDERING TEXTURE FILES ACCORDING TO VISUAL IDENTITY DATA

(71) Applicant: Adrenaline Interactive, Inc., Ann Arbor, MI (US)

(72) Inventor: Bryce Miles, Ann Arbor, MI (US)

(73) Assignee: Adrenaline Interactive, Inc., Ann Arbor, MI (US)

(21) Appl. No.: 19/644,581

(22) Filed: Apr. 10, 2026

Related U.S. Application Data
(60) Provisional application No. 63/787,637, filed on Apr. 11, 2025.
(60) Provisional application No. 63/860,619, filed on Aug. 8, 2025.

(51) Int. Cl. G06F 30/27; G06N 3/0475; G06N 3/094

(52) U.S. Cl. CPC G06F 30/27; G06N 3/0475; G06N 3/094

(57) ABSTRACT

Disclosed herein are methods and systems that use artificial intelligence techniques for rendering object files within electronic environments that are modified by visual identity data. In an embodiment, an object file, visual identity data, and a selection of an electronic environment can be provided to an AI model to cause the model to generate a second object file. In an embodiment, the AI model may be trained to generate object files based on a GAN architecture conditioned on environment style. The methods and systems allow object files to be generated that maintain important features of both the environment style of the electronic environment and the visual identity data.

### CROSS-REFERENCE TO RELATED APPLICATIONS

This application claims priority to U.S. Provisional Patent Application Ser. No. 63/860,619, filed Aug. 8, 2025, and U.S. Provisional Patent Application Ser. No. 63/787,637, filed Apr. 11, 2025, all of which are incorporated by reference in their entirety.

### TECHNICAL FIELD

The present disclosure generally relates to artificial intelligence-based rendering techniques in video games to manipulate the visual appearance of in-game objects.

### BACKGROUND

Visual rendering technology used in video games has become ubiquitous due to rapid advancements in computer graphics. These advances allow for more realistic and immersive visual experiences. Video games often need to render complex and dynamic environments that may include characters, vehicles, landscapes, and various other static or dynamic objects. Visual rendering may sometimes be used to advertise brands on in-game objects. Accurately rendering these objects is necessary for creating visually compelling and engaging advertisement campaigns.

### SUMMARY

For the aforementioned reasons, there is a desire for methods and systems that can generate modified texture files for objects that incorporate visual identifiers for brands, such as logos. Methods and systems described herein provide a trained artificial intelligence (AI) model that can predict modifications to visual identity data and can adapt the visual identity data to a visual style of an electronic environment and incorporate the adapted visual identity data into a new texture file for the object.

There is also a desire for methods and systems that can be used to train the AI model to generate the new texture files in a manner that does not overly distort elements of the visual identity data, making them unrecognizable or inconsistent with brand standards, while adapting the visual identity data to the visual style of the electronic environment.

Using the methods and systems discussed herein, a trained AI model may generate an asset that defines the visual appearance of an object in an electronic environment. The AI model may modify the visual identity data to fit the environment style of the electronic environment and incorporate the modified visual identity data into the generated asset. The visual identity data may be modified in a manner that preserves the recognizability of the associated entity through a combination of conditional inputs, masks, and specialized loss functions. For instance, recognizability can refer to how users identify an entity based on its visual identity data and being visually consistent can refer to design elements (e.g., objects) that maintain a cohesive appearance. For example, objects that are not visually consistent may appear out of place. Visually consistent objects may be more engaging to users and therefore generate more interest to the associated entity. However, overly distorting the visual identity data may prevent easily recognizability, hindering the effectiveness of an associated advertisement campaign. The described systems and methods may generate stylized assets that consistently balance modifying visual identity data to appear seamless with the electronic environment while maintaining recognizable aspects.

In some embodiments, the AI model discussed herein may use a default asset for an object, environment style, and visual identity data to predict the new stylized asset that incorporates the visual identity data. This stylized asset may be applied to the object to change the object's appearance in the electronic environment. The electronic environment may refer to any electronic framework that renders objects on a user device. For example, an electronic environment may refer to a video game that renders objects in two or three dimensions, a virtual reality environment that generates a simulated space that can mimic the real world, or an augmented reality application that overlays digital information, including objects, in the real world. Using methods and systems discussed herein, the AI model may be trained using a conditional generative adversarial network (GAN), allowing the AI model to consistently handle a diverse range of environment styles with high fidelity to recognizability of the visual identity data and seamless visual integration with the electronic environment. For instance, the AI model may be trained to modify resolution, color palette, shading, art style, or other aspects of the visual identity data to generate a stylized asset that is visually consistent with the electronic environment.

In one embodiment, a method may comprise receiving, by a processor, a selection of an object file corresponding to an object to be rendered within an electronic environment in accordance with a texture file that corresponds to a mesh defining a geometric structure of the object; receiving, by the processor, a selection of the electronic environment to include the object file; receiving, by the processor, visual identity data to modify the texture file associated with the object file to generate a second object file, such that a rendering of the second object file within the electronic environment includes a visual attribute of the visual identity data; executing, by the processor, an artificial intelligence model to generate the second object file based on the object file and the visual identity data, wherein the artificial intelligence model is configured to ingest visual attributes associated with the electronic environment and the visual identity data and predict a modification to the texture file of the object file to generate a second texture file; and transmitting, by the processor, the second object file for rendering by a user device as a part of rendering the electronic environment, wherein rendering the second object file comprises rendering the second texture file according to changes of the geometric structure of the mesh.

The artificial intelligence model may be trained using a generative adversarial network (GAN) network including a generator model and a discriminator model.

The artificial intelligence model may be trained using at least one of adversarial loss, content preservation loss, and color consistency loss.

The artificial intelligence model may be trained with a training data set including training visual identity data, an environment style, and a first training asset that is not generated by the generator model by a process including: generating, by the generator model, a second training asset based on the training visual identity data and the environment style; and determining, by the discriminator model, a first output indicating whether the second training asset is generated by the generator model; and adjusting at least one weight of the generator model based on a loss determined based on from the first output and the second output.

The artificial intelligence model may generate the second object file based on modifying a first resolution of the visual identity data based on a second resolution of the object file.

The artificial intelligence model may generate the second object file based on modifying one or more visual elements of the visual identity data to conform to an environment style associated with the electronic environment.

The method may further include identifying, by the processor, a compatibility score based on a first set of user attributes associated with the electronic environment and a second set of user attributes associated with an organization represented by the visual identity data; and recommending, by the processor, the electronic environment based on the compatibility score satisfying a compatibility threshold.

The visual identity data may include a mask indicating a portion of the visual identity data that is to be minimally modified.

In another embodiment, a computer system may include a computer-readable medium storage comprising a set of non-transitory instructions, that when executed, cause a processor to: receive a selection of an object file corresponding to an object to be rendered within an electronic environment in accordance with a texture file that corresponds to a mesh defining a geometric structure of the object; receive a selection of the electronic environment to include the object file; receive visual identity data to modify the texture file associated with the object file to generate a second object file, such that a rendering of the second object file within the electronic environment includes a visual attribute of the visual identity data; execute an artificial intelligence model to generate the second object file based on the object file and the visual identity data, wherein the artificial intelligence model is configured to ingest visual attributes associated with the electronic environment and the visual identity data and predict a modification to the texture file of the object file to generate a second texture file; and transmit the second object file for rendering by a user device as a part of rendering the electronic environment, wherein rendering the second object file comprises rendering the second texture file according to changes of the geometric structure of the mesh.

The artificial intelligence model may be trained using a generative adversarial network (GAN) network including a generator model and a discriminator model.

The artificial intelligence model may be trained using at least one of adversarial loss, content preservation loss, and color consistency loss.

The GAN network may be configured to train the artificial intelligence model with a training data set comprising training visual identity data, an environment style, and a first training asset by a process comprising: generating, by the generator model, a second training asset based on the training visual identity data and the environment style; determining, by the discriminator model in the GAN network, a first output indicating whether the second training asset is generated by the generator model; determining, by the discriminator model, a second output indicating whether the first training asset is generated by the generator model; and adjusting at least one weight of the generator model based on a loss determined based on from the first output and the second output.

The artificial intelligence model may generate the second object file based on modifying a first resolution of the visual identity data based on a second resolution of the object file.

The non-transitory instructions may further cause the processor to identify a compatibility score based on a first set of user attributes associated with the electronic environment and a second set of user attributes associated with an organization represented by the visual identity data; and recommend the electronic environment based on the compatibility score satisfying a compatibility threshold.

The visual identity data may include a mask indicating a portion of the visual identity data that is to be minimally modified.

The texture file may include a plurality of frames each representing a perspective of the object and the modification to the object file is predicted for each frame.

The modification may include a filter that is overlayed on the texture file and generating the second object file comprises applying the filter to the object file.

### BRIEF DESCRIPTION OF THE DRAWINGS

Non-limiting embodiments of the present disclosure are described by way of example concerning the accompanying figures, which are schematic and are not intended to be drawn to scale. Unless indicated as representing the background art, the figures represent aspects of the disclosure.

FIG. 1 illustrates a system for rendering branded assets, according to an embodiment.

FIG. 2 illustrates a flow diagram of a method of training an AI-enabled asset branding platform, according to an embodiment.

FIG. 3 illustrates input and output data of an AI-enabled asset branding platform, according to an embodiment.

FIG. 4 illustrates environment styles of electronic environments, according to an embodiment.

FIG. 5 illustrates a diagram of a process for implementing branded assets into an electronic environment, according to an embodiment.

FIGS. 6A-6C illustrate example branded assets, according to an embodiment.

FIG. 7 illustrates a flow diagram of a process for rendering branded assets, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting to the subject matter presented.

By implementing the methods described herein, a system may use a trained AI model to generate a stylized asset that defines the appearance of an object in an electronic environment (e.g., texture file). The electronic environment may be a video game, virtual reality platform, or other electronic space that presents objects to users. The stylized asset may incorporate visual identity data that includes visually identifiable indicators of an entity, such as a logo. There is a desire to maintain recognizability of the visual identity data while incorporating it into the electronic environment such that it looks visually consistent with the environment style of the electronic environment to create a visually compelling advertisement campaign. This approach may ensure that the brand's core elements are preserved while seamlessly integrating with the digital aesthetics, enhancing overall engagement and appeal. The system may train the AI model on style conditions indicating a target environment style and using methods such as losses that penalize some distortions of the visual identity data and/or masks that preserve the most identifiable elements. Accordingly, using the methods discussed herein, the system may consistently generate stylized assets that incorporate visual identity data in a manner that is visually seamless with the electronic environment. These stylized assets may, for instance, be used to execute engaging advertisement campaigns for entities associated with the visual identity data.

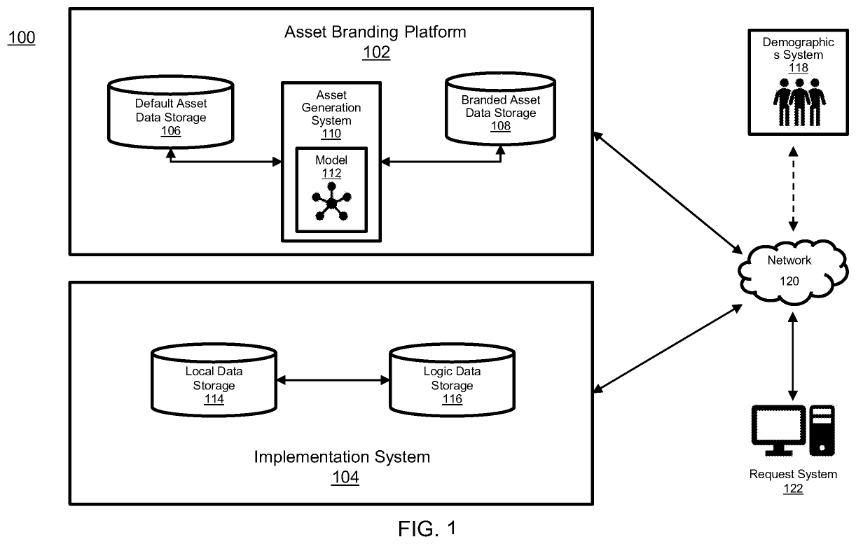

FIG. 1 illustrates a system for generating branded assets, according to an embodiment. The system 100 may include asset branding platform 102, implementation system 104, demographics system 118, and request system 122. The asset branding platform 102 may include default asset data storage 106, asset generation system 110, and branded asset data storage 108. The asset generation system 110 may include model 112. The implementation system 104 may include local data storage 114 and logic data storage 116. The system 100 is not confined to the asset described herein and may include additional or other asset not shown for brevity, which are to be considered within the scope of the embodiments described herein.

The above-mentioned asset may be connected through a network 120. Examples of the network 120 may include, but are not limited to, private or public LAN, WLAN, MAN, WAN, and the Internet. The network 120 may include wired and/or wireless communications according to one or more standards and/or via one or more transport mediums.

The communication over the network 120 may be performed in accordance with various communication protocols such as Transmission Control Protocol and Internet Protocol (TCP/IP), User Datagram Protocol (UDP), and IEEE communication protocols. In one example, the network 120 may include wireless communications according to Bluetooth specification sets or another standard or proprietary wireless communication protocol. In another example, the network 120 may also include communications over a cellular network, including, for example, a GSM (Global System for Mobile Communications), CDMA (Code Division Multiple Access), or an EDGE (Enhanced Data for Global Evolution) network.

The system 100 illustrates an example of a system architecture and asset that can be used to train and execute one or more AI models, such the model 112. Specifically, as depicted in FIG. 1 and described herein, the asset generation system 110 can use the methods discussed herein to train the model 112 using data retrieved from the default asset data storage 106 and/or the branded asset data storage 108. When the model 112 has been trained, the request system 122 may transmit a request to generate a branded object. For example, the request system 122 may transmit a request indicating an object, where the object includes an asset that defines the object's visual appearance, and visual identity data for the asset to be modified with. The AI model may ingest the asset and visual identity data to predict (e.g., generate) a branded asset that may replace the default asset of the object to form a branded object. This branded object may be transmitted to implementation system 104 to be incorporated into an electronic environment, such as a video game.

The request system 122 can be a device configured to receive requests to generate a branded object. For example, the device (e.g., laptop, mobile device, and/or the like) may receive a request to generate a branded object and a selection of the object and/or visual identity data to be used to generate the branded object. In some examples, the request system 122 may generate a graphical user interface (GUI). In these examples, the request system 122 may receive the request and associated selections via the GUI. In some examples, request may indicate a selection of an asset (e.g., default asset associated with the object) from the default asset data storage 106 and/or visual identity data from the branded asset data storage 108. For example, the user may select (e.g., via a checkbox, drop-down menu, and/or the like) the asset and/or visual identity data from a list of available assets in the default asset data storage 106 or visual identity data in the branded asset data storage 108. In some examples, the request may include an asset (e.g., asset file or object file including the asset file) and/or visual identity data to be used. For example, the object file and/or visual identity data may be uploaded to the request system 122 alongside the request. In some examples, the request may include an environment style. For example, the request may indicate a style from a list of available styles associated with the asset branding platform 102 or include a style vector indicating one or more style selections that the branded object should conform to. The environment style may be a visual style (e.g., color scheme, pixel resolution, degree of realism, shading, and/or the like) associated with the electronic environment. In some examples, the request may include deployment information indicating deployment rules for the associated branded object. For example, the request may include an indication of a time frame (e.g., a start time and an end time) for the branded object to be featured in the game. As another example, the request may include additional files (e.g., audio files) to be incorporated into deployment of the branded object in the electronic environment. As yet another example, the request may include logic rules (e.g., defining behavior of the branded object, interactions with other objects, and/or the like) for how the branded objects behaves in the electronic environment. In this example, the included logic rules may modify the logic rules defining behavior of the object including the default asset.

The asset branding platform 102 can be a system configured to modify an object according to visual identity data based on a request from the request system 122. For example, the asset branding platform 102 can receive a request to generate a branded object including a selection of an object (e.g., asset of an object) and visual identity data. The asset branding platform 102 may generate a branded asset based on the selected object and visual identity data. In some examples, the asset branding platform 102 may be configured to provide the branded object (e.g., the branded asset or the branded object file including the branded asset) to an electronic environment. For example, the asset branding platform 102 may provide the branded object to the implementation system 104. In an example, the asset branding platform 102 may transmit the branded object to the implementation system 104 along with deployment information including logic for deployment of the branded object in the electronic environment. In some examples, the asset branding platform 102 may support an application programming interface (API)-based interface for batch processing or integration with systems such as the implementation system 104 and the request system 122. For example, the API-based interface may allow for automated submission of requests, retrieval of processing results, and seamless integration with existing workflows in these systems. In some examples, the asset branding platform 102 may be a web service that can scale horizontally in the cloud.

The default asset data storage 106 can be a database that includes a plurality of default assets associated with objects of the electronic environment. Objects may represent elements (e.g., characters, items, environmental features, and/or the like) of the electronic environment. In some examples, objects (e.g., object files) may include a plurality of assets (e.g., files), such as texture files (e.g., .png, .jpg, and/or the like), 3D models (e.g., .obj, .fbx, and/or the like), scripts (e.g., .cs, .js, and/or the like) that define aspects of the object, such as appearance or behavior. In some examples, the default asset data storage 106 may include a plurality of assets from which the request system 122 can select. In these examples, the default asset data storage 106 can include complete object files including the asset files or asset files with an indication of the associated object. In some examples, the default asset data storage 106 may include asset training data sets. For example, an asset training data set may include sets of a default asset, environment style, and/or visual identity data that can be used to train the model 112 to generate branded assets. In this example, the asset training data set may include a set of default (e.g., not branded or stylized) assets. In, an example the sets of data in the asset training data set may also include a stylized asset. In this example, the stylized assets may represent an ideal generation of a branded asset based on a default asset in the set of unbranded objects and a visual identity data in the brand training data set. In an example, part or all of the training data set may be stored in the branded asset data storage 108. In some examples, the object data storage may receive data from external sources, such as the request system 122. For example, objects (e.g., or assets of the objects) may be submitted to the default asset data storage 106 along with a request to modify the asset of the object. Additionally, or alternatively, objects may be transmitted to the default asset data storage 106 by the implementation system 104. For example, the implementation system 104 may receive a set of objects associated with an electronic environment of the implementation system 104. In an example, the asset branding platform 102 may retrieve objects (e.g., or asset of the objects) from the implementation system 104 (e.g., in response to a request from the request system 122).

The branded asset data storage 108 can be a database that includes visual identity data and/or branded assets generated by the asset generation system 110. Visual identity data may include logo data (e.g., a file including an image of a logo), colors (e.g., defined in a code format, such as hexadecimal), fonts (e.g., font name, font file, and/or the like), slogans (e.g., text string), indication of objects (e.g., text string), and/or audio elements (e.g., sound elements) that are important to the identity of an entity (e.g., brands, organizations, and/or the like). In some examples, the branded asset data storage 108 may receive data from external sources. For example, the branded asset data storage 108 may receive data from the request system 122. As an example, visual identity data may be submitted to the identity asset storage along with a request to modify an object in the object data storage. In this example, the object may be modified (e.g., branded) based on the submitted visual identity data. In an example, the branded object may be stored in the branded asset data storage 108.

The asset generation system 110 can be a system configured to modify an asset of an object based on visual identity data. For example, the asset generation system 110 can be configured to generate a branded object based on visual identity data and an object indicated by a request received from the request system 122. In some examples, the asset generation system 110 can be configured to generate branded objects (e.g., branded assets of objects) according to an environment style. For example, the asset generation system 110 can be configured to generate a branded object according to a style code indicated by the associated request. The style code may correspond to a set of features (e.g., color palette, resolution, shading, and/or the like) associated with an electronic environment. As another example, the asset generation system 110 can be configured to generate a branded object according to a style vector submitted with the request indicating a set of features. As yet another example, the asset generation system 110 can be configured to generate the style vector. For example, the asset generation system 110 may encode a style vector based on a reference image. The reference image may be a screen capture and/or asset (e.g., texture file) of an object from the electronic environment that the branded object will be deployed in. In an example, the reference image may be the object associated with the request. In an example, the asset generation system 110 may embed features (e.g., color edges, spatial relationships, semantic content, and/or the like) of the reference image into the style vector using an embedding model (e.g., convolutional neural network (CNN), vision transformers (ViT), and/or the like). As another example, the asset generation system 110 may automatically select the style code based on the object. For example, object may include object metadata indicating a style code.

In some embodiments, the asset generation system 110 may be a system configured to train and/or execute the model 112. For example, the asset generation system 110 may train the model 112 based on a visual identity data training data set and an asset training data set including pairs of default assets and stylized assets, where the stylized assets are ideal versions of an asset generated based on the default asset and/or corresponding visual identity data in the training data set. In some examples, the asset generation system 110 may train the model 112 using a generative adversarial network (GAN) comprising a generator (e.g., the model 112) configured to generate branded objects and a discriminator configured to determine whether a branded object is generated by the generator or is from the training data set (e.g., an ideal branded object). In some examples, the asset generation system 110 may train the model 112 to generate branded assets that align with a target game style. For example, the asset generation system 110 may condition the model 112 on a style code. In this example, the asset generation system 110 may include style codes corresponding to sets of features (e.g., color palette, resolution, shading, and/or the like). In some examples, the discriminator may determine if an asset is from the training data set, or the generator based on the style code. As an example, the discriminator may identify that an asset is produced by the generator based on determining that it does not properly conform to the style code.

The model 112 may be an artificial intelligence (AI) model configured to generate a modified version of the object associated with the request based on the visual identity data. The model 112 may be a neural network configured to generate images (e.g., assets of the object that are texture files) based on learning patterns and features of the training data set. For example, the model 112 may be trained to maintain or modify certain features of input data based on learned patterns. In some examples, the model 112 may be trained to modify visual aspects of default assets to include visual aspects of the visual identity data. As an example, the object may be modified to include colors associated with the visual identity data, objects associated with the visual identity data, logos associated with the visual identity data, and/or the like. In some examples, the model 112 may modify the visual identity data to align with an environment style. For example, the model 112 may receive a style vector indicating a set of features (e.g., associated with a style code identified by the asset generation system 110 or submitted with the request). In this example, the model may modify visual aspects of the visual identity data (e.g., change saturation of colors, change resolution, and/or the like) to align with the environmental style. In some examples, the visual identity data that has been modified to align with the environment may be used to modify visual aspects of the default asset. In these examples, the resulting branded asset may include visual aspects of the visual identity data that have been modified (e.g., adjusted in color palette, resolution, and/or the like) to fit the environment style of the associated electronic environment. In some examples

In some embodiments, the model 112 may be conditioned to generate branded assets for a plurality of environment styles based on a style code. In some examples, the model 112 may be trained to be executed with a preset selection of styles (e.g., represented by style codes). Additionally, or alternatively, the model 112 may be trained to generate branded assets in new environment styles input by the user (e.g., represented by a style vector). In some examples, the style code may be associated with a set of features representing an environmental style in the asset generation system 110. In these examples, the model 112 may be conditioned by the asset generation system 110 on these style codes during training. In some examples, the style code may be a style vector (e.g., submitted by the user) indicating set of features. In these examples, the model 112 may generate branded assets based on numbers indicating features within the style vector. In some examples, the model 112 may be an ensemble of models.

The implementation system 104 can be a system (e.g., engine, framework, and/or the like) configured to generate and/or manage electronic environments. implement the branded object into an electronic environment. For instance, the implementation system 104 can generate an electronic environment (e.g., video game, virtual reality environment, augmented reality environment, simulation, and/or the like) for a user device, incorporating visual display graphics and/or auditory elements. The electronic environment may process user input and dynamically generate responses, such as modifying visual display elements. In some examples, the electronic environment may be generated on a user device (e.g., mobile device, laptop, gaming console, and/or the like). In some examples, the electronic environment may include a plurality of objects. For example, the electronic environment may display objects as part of the environment presented to the user. In an example, the objects may respond to user input. For example, interactive objects within the electronic environment can dynamically adjust their behavior based on user actions.

In some examples, the implementation system 104 can be a device configured to generate an electronic environment. For example, the implementation system 104 can implement the electronic environment based on data and/or logic that has been downloaded to the device. In some examples, the electronic environment may be implemented regardless of connection to a network (e.g., such as the network 120). For example, the implementation system 104 may be a component of a user device that renders the electronic environment. In this example, the electronic environment may be updated (e.g., objects may be added and/or removed) based on connection to the network 120. For example, based on connecting to the network 120, the implementation system 104 may receive and/or remove a branded object that can be deployed in an electronic environment. In some examples, the implementation system 104 may remove a branded object according to logic (e.g., logic indicated an end date for the branded object) regardless of connectivity to the network 120. In some examples, the implementation system 104 may generate the branded object based on receiving the branded asset from the asset branding platform 102. In this example, the implementation system 104 may generate the branded object based on replacing the default asset (e.g., default texture file) of the object with the branded asset (e.g., branded texture file) generated by the asset generation system 110. The branded object may replace the object or be added as an additional object to the local data storage 114.

In some examples, the implementation system 104 can be separate from the user device on which the electronic environment is implemented. For example, the user device can interact with the implementation system 104 over a network (e.g., such as the network 120) to receive data associated with the electronic environment and transmit user input. In these examples, the implementation system 104 may be a cloud-based server.

The local data storage 114 can be a database that includes objects which can populate the electronic environment. For example, the local data storage 114 can include object files that define objects which can appear in the electronic environment. The local data storage 114 may also include environmental settings that define the background that the objects can appear in (e.g., lighting, weather conditions, background sound, and/or the like). In some examples, the local data storage 114 may receive branded objects from the asset generation system 110. In some examples, the objects may be deployed (e.g., retrieved for rendering in the electronic environment) from the local data storage 114 based on logic rules associated with each object in the local data storage 114.

The logic data storage 116 can be a database that includes logic rules that establishes rules governing the behavior of the electronic environment. For example, the logic rules may define the role of objects in the electronic environment. As an example, the logic rules may define when objects appear. Based on the logic rules in the logic data storage 116, the implementation system 104 may retrieve an object from the local data storage 114. As an example, the logic rules may establish a campaign (e.g., marketing campaign) that determines when a branded object should appear and/or disappear in the electronic environment. In some examples, request system 122 may establish campaign rules including a start and/or end time of a branded object within the electronic environment. In these examples, the campaign rules may be transmitted to the implementation system 104 (e.g., along with the branded object) and stored in the logic data storage 116. The implementation system 104 may retrieve the branded object from the local data storage 114 based on the campaign rules in the logic data storage 116.

The demographics system 118 can be a system that is configured to determine a match in demographics between the entities associated with the visual identity data and electronic environments. For example, the demographics system 118 may receive a first set of demographics information associated with users, the electronic environment (e.g., from the implementation system 104 or another source), and a second set of demographics associated with the brand (e.g., form the request system 122) based on determining a match (e.g., satisfying a threshold match score) between the first set of demographics and the second set of demographics, the demographics system 118 may recommend the electronic environment to the use system for a campaign involving a branded object.

In some embodiments, the demographics system 118 may identify individual executions (e.g., individual users and/or sessions of users) of the electronic environment to deploy a branded object in. For example, the demographics system 118 may identify a match between demographics attributed to a user associated with an execution of the electronic environment and the second set of demographics associated with the brand. In this example, the demographics system 118 may submit a request to generate a branded object associated with the brand and the electronic environment based on identifying the match. The resulting branded object may be transmitted to the implementation system 104 and subsequently deployed in the electronic environment of the user. In some embodiments, the demographics system 118 may receive a campaign request (e.g., from the request system 122) requesting that branded objects associated with the visual identity data be displayed to a certain demographic of users. In these embodiments, the demographics system 118 may identify a match between the demographics of the brand and the demographics of at least one user and submit a request for a branded object to be generated and displayed in the electronic environment of the user.

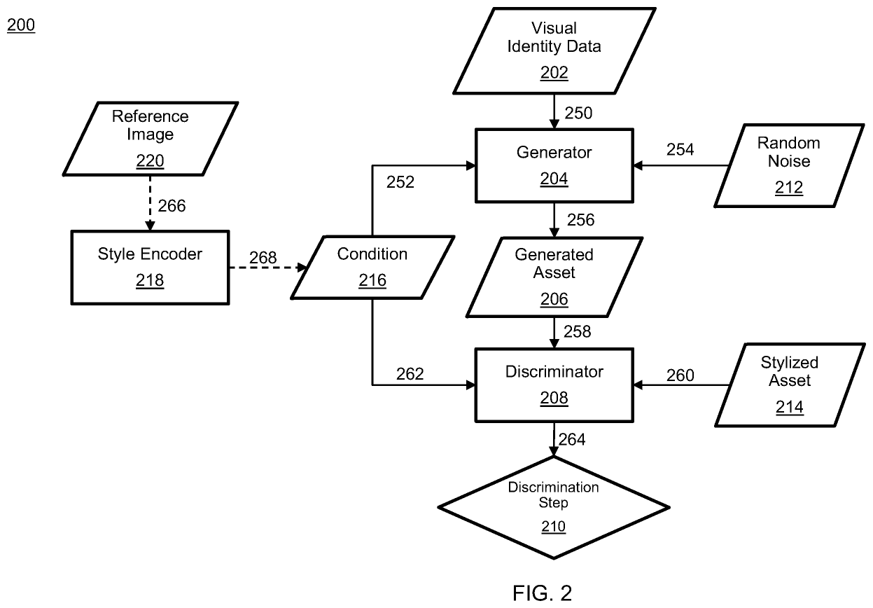

FIG. 2 illustrates a flow diagram of a method 200 of training an AI-enabled object branding system, according to an embodiment. In some examples, the flow diagram may represent training an AI model through a generative adversarial network (GAN) including a generator 204 and a discriminator 208. The method 200 may include steps 250-264, may be implemented by components including a style encoder 218, generator 204, and discriminator 208, and may generate and/or ingest input and output data including reference image 220, condition 216, visual identity data 202, generated asset 206, random noise 212, and stylized asset 214. However, other embodiments may include additional or alternative elements (e.g., steps, components, inputs, and/or outputs) or may omit one or more elements. The resulting trained generator 204 may represent a model (e.g., model 112 of FIG. 1) that can be used to generate assets based at least on an input of a condition 216 (e.g., environmental style) and visual identity data 202.

At step 250, the generator 204 may receive the visual identity data 202. For example, the generator 204 may receive logos, banners, icons, colors, and/or the like associated with the visual identity of an entity (e.g., a brand). In an example, the visual identity data 202 may include a mask indicating a critical portion of the data. (e.g., a logo). In this example, the mask may be associated with a color variance threshold indicating an acceptable pixel-wise threshold for modifying colors within the masked region. Additionally or alternatively, the visual identity data 202 may be associated with a color variance threshold indicating an acceptable pixel-wise threshold for variance of the color histogram (e.g., within the masked region and/or entire asset) of the generated asset 206 and the visual identity data 202.

At step 252, the generator 204 may receive the condition 216. In an example, the condition 216 may be an indication of a style from a plurality of styles (e.g., a one hot label corresponding to a style vector within a system training the generator 204, such as the asset generation system 110 of FIG. 1). In another example, the condition 216 may be a style vector that indicates a plurality of attributes (e.g., color, texture, patterns, shading, resolution, and/or the like). In some examples, the condition 216 may be generated based on a reference image 220.

At step 266, the style encoder 218 may receive the reference image 220. The reference image 220 may be an image from the electronic environment (e.g., display content capture, object file, texture file of an object, and/or the like). In an example, the reference image 220 may be associated with the same electronic environment as the stylized asset 214. In some examples, the reference image 220 may be a texture file (e.g., such as a default asset from the default asset data storage 106 of FIG. 1). In these examples, the reference image 220 may be provided to the generator 204. For example, the generated asset 206 may be a modified version of the reference image 220 and/or the same class of object (e.g., car, tree, and/or the like) as the reference image 220.

At step 268, the style encoder 218 may generate the condition 216 based on the reference image 220. For example, the style encoder 218 may encode a style vector as the condition 216 based on one or more visual aspects of the reference image 220. As an example, the style encoder 218 may determine a resolution, saturation, shading, and/or the like of the reference image 220. In some examples, the style vector may include indications of object types (e.g., the vector may include strings indicating themes and/or object classes included in the associated electronic environment). In these examples, the generator 204 may be trained to generate generated asset 206 based on input comprising a style vector and visual identity data 202 and may determine the generated asset 206's form (e.g., car, tree, t-shirt, and/or the like) based on the condition 216 comprising the style vector. In some examples, the style encoder 218 may embed the features of the reference image 220 as the condition 216. For example, the style coder may include a convolutional neural network (CNN) configured to generate numerical representations of the reference image 220 as the condition 216.

At step 254, the generator 204 may receive random noise 212. For example, the generator 204 may receive random noise 212 and generate the generated asset 206 based on the random noise 212. The random noise 212 may be a vector. In an example, the generator 204 may map the random noise 212 to distributions that resemble stylized assets in the training data. For example, the generator 204 may be a neural network that applies learned weights and biases to the random noise 212 to transform it into the generated asset 206. Over the course of training, the generator 204 may improve its ability to generate assets that resemble stylized assets, such as the stylized asset 214, based on minimizing a loss. In an example where the stylized asset 214 is generated based on the visual identity data 202 and the condition 216, the loss may be the difference (e.g., pixel-wise and/or feature-based difference) between the generated asset 206 and the stylized asset 214.

At step 256, the generator 204 may generate (e.g., predict) the generated asset 206. For example, the generator 204 may generate the generated asset 206 based on the condition 216, visual identity data 202, and/or random noise 212. Based on these inputs, the generator 204 may predict an output including an image comprising visual aspects of the visual identity data 202 that have been modified based on the condition 216. In some examples, the generator 204 may generate the generated asset 206 as a version of an object (e.g., including a default asset) of an electronic environment (e.g., associated with the condition 216) that has been modified based on visual aspects of the visual identity data 202. In these examples, visual aspects of the visual identity data 202 may be modified based on the condition 216. As an example, the resolution of visual aspects of the visual identity data 202 may be modified according to the condition 216. In examples where the visual identity data 202 is associated with a mask, the masked portion of the visual identity data 202 (e.g., logo) may not be modified or may only be modified according to some features of the condition 216 (e.g., the resolution may be modified but the saturation may not).

At step 258, the generated asset 206 may be provided to the discriminator 208. In some examples, the discriminator 208 may receive the generated asset 206 along with the corresponding stylized asset 214. In some examples, the discriminator 208 may receive several generated assets including the generated asset 206 before discriminating which assets are part of the training data set (e.g., are stylized assets such as the stylized asset 214) and which assets are generated by the generator 204.

At step 260, the stylized asset 214 may be provided to the discriminator 208. For example, the stylized asset 214 may be provided from a training data set including sets of visual identity data, conditions (e.g., or reference images), and stylized assets. The stylized asset 214 may represent an ideal version of an asset that incorporates visual identity data, such as the visual identity data 202 that has been modified based on an environment style. In some examples, the stylized asset 214 may be generated by a person. For example, the stylized asset 214 may be a human-generated rendering of an asset. In some examples, the stylized asset 214 may be generated by a model. For example, the stylized asset 214 may be generated by a model, such as the generator 204 (e.g., or a fully trained version of the generator 204). In these examples, the stylized asset 214 may be selected by a person. For example, output including stylized assets may be adjudicated by one or more people to determine that they are an ideal version of a stylized asset. In some examples, the stylized asset 214 may be associated with (e.g., generated based on) the visual identity data 202. For example, the stylized asset 214 may incorporate the visual identity data 202. In some examples, the stylized asset 214 may be associated with (e.g., generated based on) the condition 216.

At step 262, the condition 216 may be provided to the discriminator 208. For example, the discriminator 208 may perform the discrimination step 210 based on the condition 216. The condition 216 may indicate a plurality of features associated with an electronic environment. In some examples, the discriminator 208 may determine that an asset is the generated asset 206 based on determining that the asset does not adequately align with these features. For example, the discriminator 208 may determine that an asset is not within a threshold variance or not within a range associated with the features of the condition 216.

At step 264, the discriminator 208 may perform the discrimination step 210 to determine whether an asset is the generated asset 206 or the stylized asset 214. For example, the discriminator 208 may receive an asset from a set of assets including the generated asset 206 and the stylized asset 214 and determine whether the asset is the generated asset 206 or the stylized asset 214. In this example, the set of assets may include a plurality of generated assets and stylized assets. In an example, the discriminator 208 may assign a label to each asset in the set of assets. In some examples, parameters (e.g., weights) of the generator 204 and/or discriminator 208 may be updated based on whether assets in the set of assets were correctly identified at the discrimination step 210.

In some embodiments, the generator 204 and/or discriminator 208 may be updated based on loss calculations. For example, the weights of the generator 204 and/or discriminator 208 may be adjusted based on at least one loss function. In some examples, the generator 204 and/or discriminator 208 may be updated based on adversarial loss. Adversarial loss may be based on the accuracy of the discriminator 208 at the discrimination step 210. For example, the generator 204 may be updated to produce images that are closer to the stylized asset 214. As another example, the discriminator 208 may be updated to more accurately discriminate between the generated asset 206 and the stylized asset 214. In some examples, the generator 204 and/or discriminator 208 may be updated based on content preservation loss. Content preservation loss may be based on distortion of designated areas of the visual identity data 202 in the generated asset 206. For example, a loss may be determined between an original region of the visual identity data 202 (e.g., a region of a logo) and a corresponding generated region of the generated asset 206.

In some embodiments, the original region may be determined based on a mask within the visual identity data 202 that identifies a specific area of interest (e.g., logo). In an example, the content preservation loss may be a pixel-wise loss. For example, the content preservation loss may be an L1 or L2 pixel-wise loss between the original region and the generated region. In another example, the content preservation loss may be a feature-based loss. For example, the content preservation loss may be calculated by convolution neural network (CNN) such as a visual geometry group (VGG) model. In this example, the VGG model may calculate a perceptual loss between the original region and the generated region as the feature-based loss. The VGG model may identify features in the generated and original regions by using convolutional layers with small filters to capture fine details and patterns and then determine a difference between the features as the perceptual loss. In described examples, the content preservation loss may indicate how much the original region (e.g., logo) has been distorted in the generated asset 206. The generator 204 and/or discriminator 208 may be updated to generate assets that minimize this distortion or discriminate based on identifying this distortion, respectively.

In an example, the content preservation loss may be a combination (e.g., weighted or unweighted) of pixel-based loss and feature-based loss. In some examples, the generator 204 and/or discriminator 208 may be updated based on color consistency loss. Color consistency loss may be based on distortion of colors associated with the visual identity data 202. For example, colors of the generated asset 206 may be adjusted based on the condition 216. As an example, the saturation of an image may be increased to better fit with an environment style associated with the condition 216. In an example, the color consistency loss may be determined based on comparing colors of the original area of the generated asset 206 and colors of the visual identity data 202. In this example, color consistency loss may determine a degree to which colors of the generated asset 206 deviate from corresponding colors of the visual identity data 202.

The color consistency loss may be determined based on color histogram matching (e.g., how closely the color histogram of the generated area matches the original area) or direct pixel-level comparison. In an example, colors of the original area and/or entire generated asset 206 may be associated with an acceptable level of variance. In this example, color consistency loss may be determined based on whether the colors of the generated area are within the acceptable level of variance of the colors of the original area (e.g., either pixel-wise or color histogram). Additionally, or alternatively, the color consistency loss may be determined based on the variance of a color histogram associated with the generated asset 206 and the stylized asset 214. In some examples, the generator 204 and/or discriminator 208 may be updated based on a combination (e.g., weighted or unweighted) of adversarial loss, content preservation loss, and/or color consistency loss. As a result of adjusting the weights of the generator 204 and/or discriminator 208 based on adversarial loss, content preservation loss, and/or color consistency loss, identity-defining elements of the visual identity data 202, such as logos and/or color schemes, may be retained. Furthermore, the optional mask may protect certain aspects of the visual identity data 202 from unintended distortion.

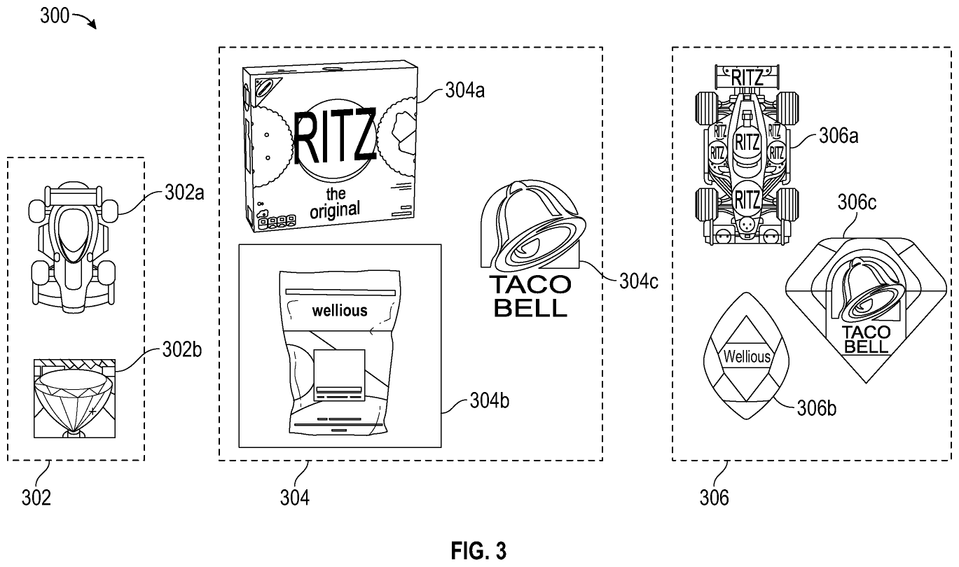

FIG. 3 illustrates input and output data 300 of an AI-enabled asset branding platform, according to an embodiment. For example, default assets 302 and visual identity data 304 may be provided to an asset branding platform (e.g., such as the asset branding platform 102 of FIG. 1) as part of a request to generate branded assets 306.

The default assets 302 may be assets (e.g., texture files) of respective first objects that define appearance of the first objects within an electronic environment. For example, the default assets 302 may be digital images that map details onto an object's surface using coordinates to align the digital image with the object's surface. As an example, the default asset 302a may define the appearance of a car in an electronic environment. In this example, modifications to the default asset 302a file can modify how the car appears in the electronic environment. These modifications may not affect how the car behaves in the electronic environment. Similarly, the default asset 302b may define the appearance of a gem in an electronic environment. In various examples, the default assets 302 may be used to add visual details to two-dimensional objects or three-dimensional objects within the electronic environment. In an example, the first objects may include additional assets that define other qualities of the first objects within their electronic environments such as deployment, interaction with other objects, and/or the like.

The visual identity data 304 may be an image that includes a visually identifiable representation of an entity. For example, the visual identity data 304 may include a logo that identifies the entity. As an example, the visual identity data 304c includes a logo for the fast-food chain Taco Bell®. In an example, the visual identity data 304 may include a mascot, color, text (e.g., including a certain phrase and/or font), color identifier, and/or the like. As an example, the visual identity data 304b includes various colors associated with the entity it identifies. The visual identity data may be a photo of a packaging associated with the entity, such as visual identity data 304a and 304c, and/or a graphical illustration of a logo, such as visual identity data 304b. In some examples, the visual identity data 304 may include a mask. For example, the visual identity data 304 may include a mask indicating special rules for a portion of the visual identity data 304 (e.g., the Taco Bell® logo in visual identity data 304c ). As an example, the mask may be associated with a threshold indicating an acceptable level of color variance between the visual identity data 304 and the branded asset 306. In some examples the mask may prevent distortion of significant parts of the visual identity data 304.

The branded assets 306 may be the output of an AI model (e.g., such as the model 112 of FIG. 1) configured to generate branded assets based on visual identity data 304. For example, the branded assets 306 may be versions of the default assets 302 that have been modified to incorporate the visual identity data 304. As an example, the branded asset 306a may be a version of the default asset 302a that has been modified to incorporate visual identity data 304a . As another example, the branded asset 306b may be a version of the default asset 302b that has been modified to incorporate visual identity data 304b . As yet another example, the branded asset 306c may be a version of the default asset 302b that has been modified to incorporate visual identity data 304c . In some examples, the visual identity data 304 may be modified to appear visually compatible with a style of an electronic environment (e.g., by modifying style, resolution, aspects of colors, and/or the like). As an example, the resolution of the RITZ^{®}logo in visual identity data 304a may be lowered before it is incorporated into the branded asset 306a . In some examples, the AI model may generate the branded assets 306 as objects of the same class (e.g., type of object) as the corresponding default asset from the default assets 302. For example, the AI model may identify an object types of default assets 302 and generate branded assets 306 based on the object types and visual identity data 304. As an example, the branded asset 306b may be generated as a gem based on the default asset 302b being identified as a gem.

In some examples, the asset branding platform may receive a request to generate a branded asset (e.g., such as the branded assets 306) comprising a default asset (e.g., such as one of the default assets 302) and/or the visual identity data (e.g., such as part of the visual identity data 304). As an example, the request can include the visual identity data 304b and the default asset 302b . In an example, the request may indicate an environment style. For example, the request may include a style code, style vector, and/or the like. In another example, the asset branding platform may generate a style vector based on a reference image. The reference image may be the default asset or an image indicated by the request. In this example, the asset branding platform may embed visual features of the reference image into the style vector. In some examples, the asset branding platform may provide the default asset, an indication of the environment style, and/or visual identity data to the AI model. The AI model may ingest the default asset, indication of the environment style, and/or visual identity data and generate a prediction based on this input. In some examples, the prediction may be a branded asset that incorporates the visual identity data and/or environment style into a new asset (e.g., texture file) for the object. The prediction may include modifying the visual identity data based on the environment style. For example, as can be observed in the branded asset 306a , the resolution of the RITZ® logo incorporated into the branded asset 306a is lower than the depiction of the logo included in the visual identity data 304a . As another example, the colors of the branded asset 306c are more saturated than corresponding colors in the visual identity data 304c .

In some examples, the asset branding platform may transmit the branded asset for rendering by a user device. For example, the asset branding platform may transmit the branded asset to an implementation system that governs the electronic environment. The implementation system may be part of the user device or be a separate system that transmits data associated with the electronic environment via a network. In some examples, the asset branding platform may generate a second object by replacing the default asset in the first object with the branded asset. As an example, the default asset 302a may be replaced with the branded asset 306a . In these examples, the asset branding platform may transmit the second object including the branded asset for rendering by the user device. Alternatively, the implementation system may generate the second object by replacing the default asset in the first object with the branded asset based on receiving the branded asset. As an example, the implementation server may receive the branded asset 306a and replace the default asset 302a with the branded asset 306a to generate the second object. In some examples, the second object may be deployed (e.g., to appear in the electronic environment) by the implementation system. For example, the implementation system may deploy the second object based on logic rules associated with the second object. In an example, the second object may be deployed in addition to or in place of the first object. In an example where the electronic environment allows cars to be raced, the second object including the branded asset 306a may be displayed as an option to race in addition to or in place of the first object including the default asset 302a . In this example, the second object may behave according to the same logic as the first object. For example, the second object may have the same controls and/or interactions with other objects in the electronic environment.

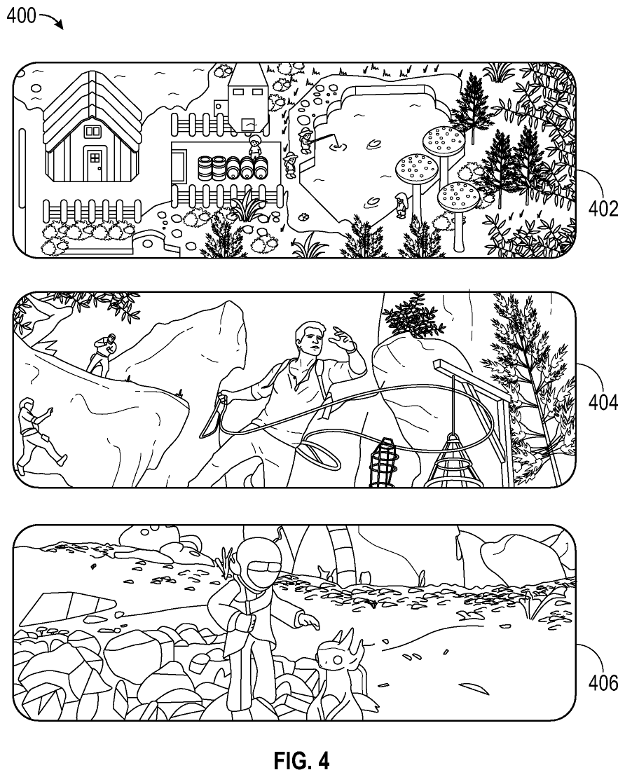

FIG. 4 illustrates environment styles 400 of electronic environments, according to an embodiment. The environment styles 400 can include pixelated environment style 402, realistic environment style 404, and low polygon environment style 406. The environment styles 400 can represent various visual styles of electronic environments. In some examples, visual identity data can be modified to fit various style features of the environment styles 400. For example, an AI model can predict branded assets that are visually consistent with their electronic environments while maintaining recognizability of entities associated with the visual identity data. As result, the branded assets can be easy to use (e.g., since they appear visually consistent to similar objects in the game), increase user engagement with the objects, and/or improve recognizability of the entities based on the branded assets.

In some embodiments, the environment styles 400 can be used as reference images to generate style vectors. For example, a style encoder (e.g., such as the style encoder 218 of FIG. 2) may embed aspects of the environment styles into a style vector. The style vector may numerically represent style features (e.g., resolution, dimensions, color palette, shading, themes of object present, and/or the like) of electronic environments. The style vector can then be used (e.g., by the AI model) to generate branded assets that are visually consistent with their respective electronic environments.

The pixelated environment style 402 may represent a two-dimensional environment style that has a relatively low resolution. In some examples, a style vector may include an indication of colors within the pixelated environment style 402. For example, the style vector can indicate color properties (e.g., hue, saturation, luminance, and/or the like) and/or color values (e.g. RGB (red, green, blue) values representing the colors that are primarily present, such as the red, yellow, blue, and/or green shades). In some examples, the style vector can indicate themes, such as types of buildings (e.g., barns), presence of nature elements (e.g., ponds, trees, mushrooms, and/or the like), and/or activities being performed (e.g., farming). In some examples, the style vector can indicate art style, such as resolution and/or shading.

The realistic environment style 404 may represent a three-dimensional environment style that mimics the appearance of real-world objects. While a two-dimensional environment may be limited to up, down, left, and/or right movement, a three-dimensional environment may allow movement in all (e.g., or nearly all) directions within a three-dimensional space. As a result, objects can rotate and turn within the three-dimensional environment, providing a more comprehensive view of the object. In examples where the electronic environment is three-dimensional, the branded asset can be a two-dimensional texture file that is mapped onto a surface of the associated 3D object during a rendering process. For example, the texture file and/or object can be associated with texture coordinates that can be utilized to display a two-dimensional image on the 3D object.

In some examples, the style vector associated with the realistic environment style 404 can indicate similar categories of features as the style vector associated with the pixelated environment style 402. For example, the style vector can indicate color values such as RGB values for the grey, green, and blue shades that are most prominent. As another example, the style vector can indicate an adventure theme based on objects such as the grappling hook, intense natural features (e.g., steep cliffs), and/or explosion.

The low polygon environment style 406 may represent a three-dimensional environment style that utilizes a relatively small number of polygons to generate shapes and textures. This can result in objects appearing angular and/or simplified within the electronic environment. In some examples, the style vector associated with the low polygon environment style 406 may indicate geometric simplicity and/or minimalistic design elements. Similar to the style vector of the realistic environment style 404, the style vector of the low polygon environment style 406 can indicate a theme of objects. For example, the style vector can indicate a futuristic theme.

In some embodiments, visual identity data can be modified based on environment styles 400. For example, visual identity data can be modified based on style vectors associated with environment styles 400. As an example, based on the pixelated environment style 402, the AI model may decrease the resolution and/or increase the saturation of visual identity data based on the style vector. As another example, based on the realistic environment style 404, the AI model may introduce realistic shading and/or add adventure elements to the visual identity data. In this example, the AI model may add adventure elements to the visual identity data. For example, the AI model can modify the bell of the Taco Bell® logo (e.g., the visual identity data 304c of FIG. 3) to look more rugged (e.g., cracked, rusty, worn and/or the like) as part of adding adventure elements to the visual identity data. As yet another example, based on the low polygon environment style 406, the AI model may simplify and/or remove design elements. In this example, the AI model may modify the Taco Bell® logo (e.g., the visual identity data 304c of FIG. 3) to integrate design elements that look futuristic (e.g., gradients, chromatic colors, and/or the like) based on the style vector associated with the low polygon environment style 406.

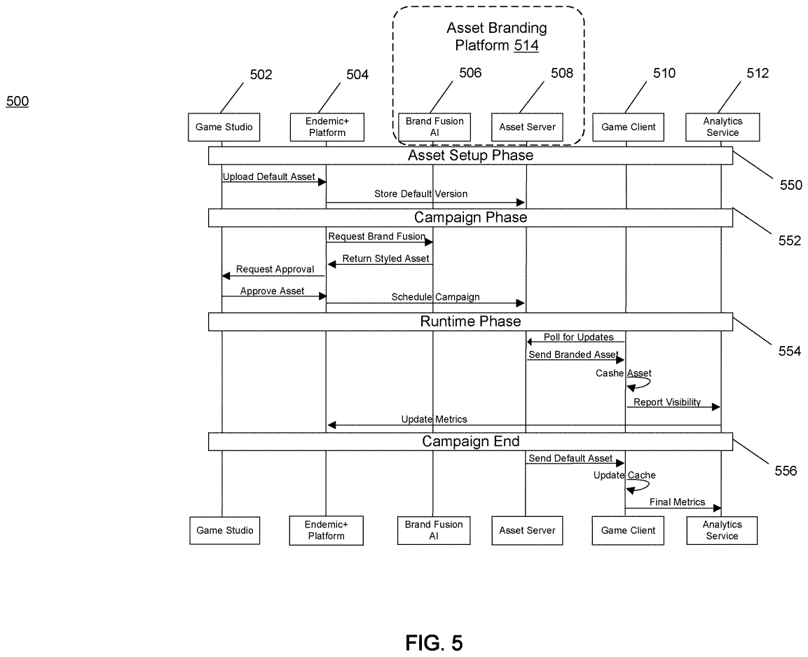

FIG. 5 illustrates a diagram of a process for implementing branded assets into an electronic environment, according to an embodiment. The process 500 may be executed by a game studio 502, request system 504, asset branding platform 514, game client 510, and/or analytics system 512. The asset branding platform 514 can include an asset generation system 506, and/or asset server 508. The request system 504 can be the same or similar to the request system 122 of FIG. 1, the asset branding platform 514 can be the same or similar to the asset branding platform 102 of FIG. 1, and/or the game client 510 can be the same or similar to the implementation system 104 of FIG. 1. The process 500 can include an asset setup phase 550, campaign phase 552, runtime phase 554, and/or campaign end phase 556.

At the asset setup phase 550, the game studio 502 can upload a default asset to the request system 504. In response to receiving the default asset, the asset request system 504 can store the default asset in the asset server 508. In some examples, the default asset may be provided as an option for entities to select (e.g., through the request system 504). In these examples, entities can indicate a default asset from the asset server 508 to generate the branded asset based on as part of the request to generate a branded asset.

At the campaign phase 552, the request system 504 can submit a request to generate a branded asset to the asset branding platform 514. In an example, the request can identify an electronic environment style (e.g., style vector and/or style identifier), default asset (e.g., such as the default asset uploaded to the asset server 508 by the game studio 502), and/or visual identity data. Based on this information, the asset generation system 506 can generate a branded asset. For example, the asset generation system 506 can generate a branded asset that incorporates the visual identity data into the default asset based on the environment style while maintaining recognizability of the visual identity data. In some examples, the asset branding platform 514 can return the branded asset to the request system 504. The request system 504 may then transmit a request for approval of the branded asset to the game studio 502. Based on receiving approval for the branded asset, the request system 504 can schedule a campaign. The campaign can indicate a timeframe that the branded asset will be present in the electronic environment, a budget for the campaign, a target demographic that the branded asset should be presented to. These indications may be stored as logic rules and transmitted to the game client along with the branded asset.

At the runtime phase 554, the game client 510 may poll the asset server 508 for updates. The updates can include new campaigns that have been scheduled by the request system 504. When new updates are available, the game client 510 can download the campaign (e.g., including the branded asset and any associated logic rules) from the asset server 508 and cache the campaign. The branded asset may be deployed in an electronic environment of the game client 510 based on the associated logic rules. In some examples, the game client 510 can track metrics indicating how often users see and/or interact with the branded assets. The game client 510 can transmit these metrics to the analytics system 512. Based on receiving these metrics, the analytics system may transmit them to the request system 504.

At the campaign end phase 556, the game client 510 can update the cache to revert back to the default asset. For example, the asset server 508 can transmit the default asset to the game client. Based on receiving the default asset, the game client 510 can update the cache to replace the branded asset with the default asset. In some examples, the game client 510 can report final metrics associated with visibility and interaction of players with the branded asset to the analytics system 512. Based on receiving these metrics, the analytics system 512 can update the request system 504.

The described process 500 for implementing branded assets can allow the game client 510 to seamlessly transition between default and branded assets. The process 500 can allow for automatic management of campaign timing through associating logic rules with branded assets. Additionally, the process 500 can allow both the entity (e.g., the entity that is utilizing the request system 504) and the game studio 502 to maintain quality control of generated branded assets through an optional approval process. Furthermore, the process 500 can allow for accurate tracking of brand exposure. As a result, the described systems and methods can increase the efficiency of generating and/or deploying branded assets by providing a streamlined workflow that facilitates selections for branded assets and automatically associates campaign logic rules with the branded assets.

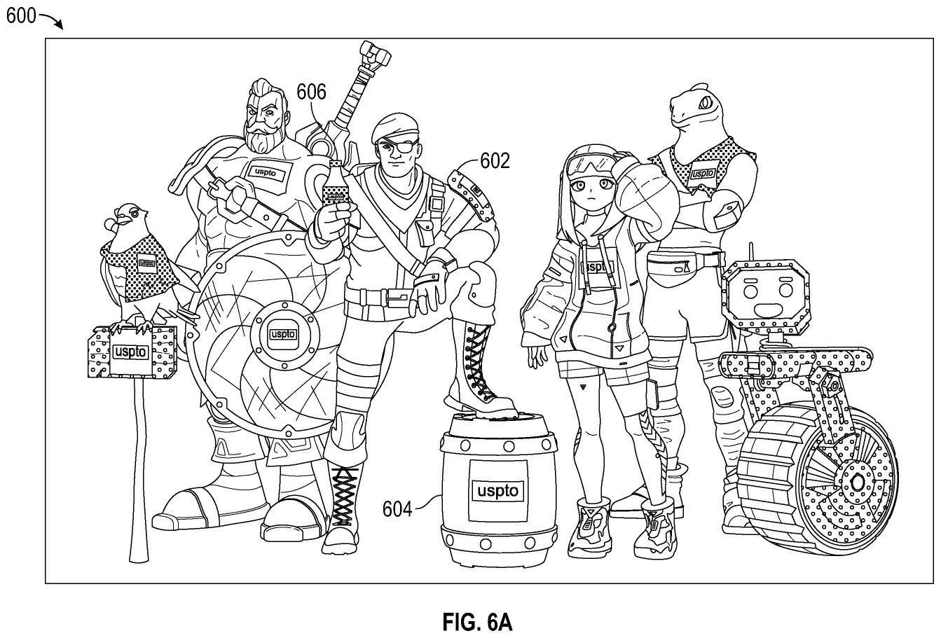

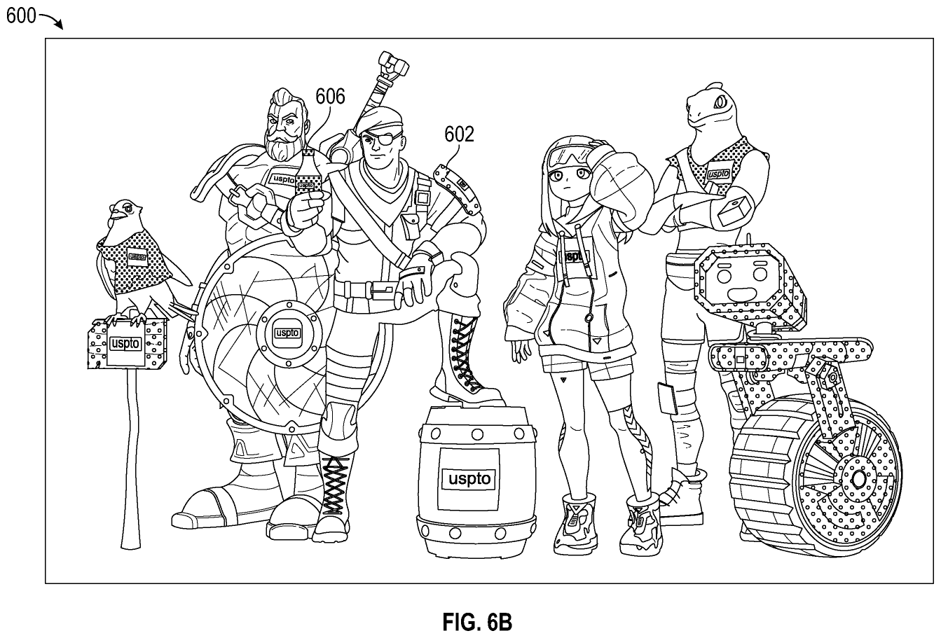

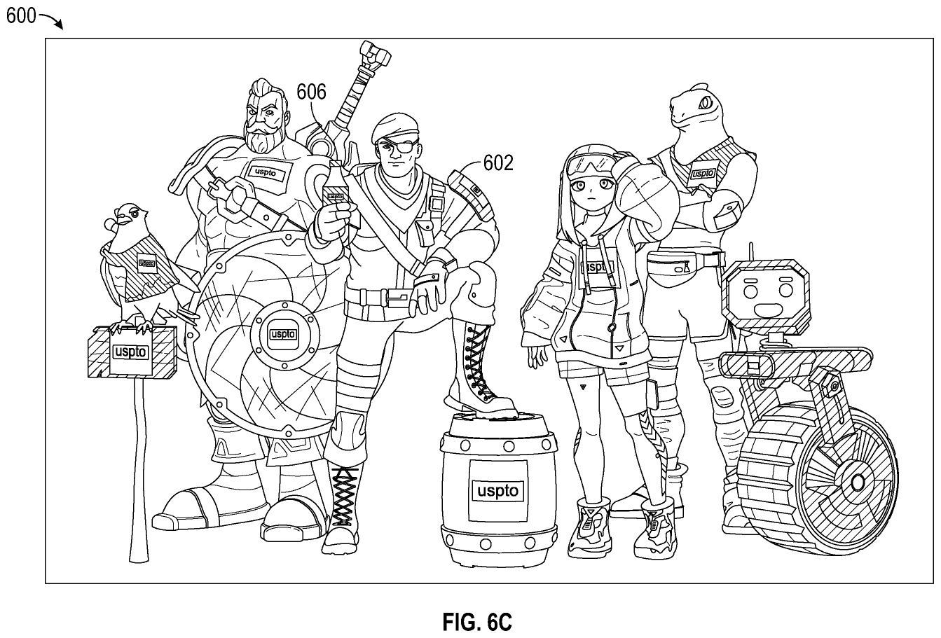

FIGS. 6A-6C illustrate example branded assets 600, according to an embodiment. The example branded assets may be generated by an asset branding platform (e.g., the asset branding platform 102 of FIG. 1). For example, the branded assets 600 may be generated by the asset branding platform in response to a request transmitted by a request system (e.g., request system 122 of FIG. 1). The request system may transmit a request including a logo (e.g., an image file including a logo image, and/or the like) and/or brand colors. As an example, FIGS. 6A-6C illustrate example branded assets 600 generated based on the logo of the United States Patent and Trademark Office (USPTO). In response to the request, the asset branding platform can generate the branded assets 600 that incorporate this logo. The branded assets 600 can also incorporate one or more colors indicated as part of the request. The branded assets 600 may represent texture files of objects in an electronic environment. By incorporating a logo to generate branded assets 600, the logo may be visually integrated into objects of the electronic environment in a manner that maintains visual coherence with elements of the objects and the electronic environment.

Referring to FIG. 6A, illustrated are branded assets 600 that incorporate the USPTO logo and two colors, teal (e.g., represented by the larger polka dot pattern such as shown by branded asset 606) and white (e.g., represented by the smaller polka dot pattern such as shown by branded asset 602). The colors may be provided as part of the request. For example, the user may indicate colors by transmitting strings representing the colors (e.g., in hexadecimal code, and/or the like). In an alternative example, the asset branding platform may identify the colors based on colors present in an image file including the logo. The asset branding platform may incorporate colors included in the request into various components of assets. As an example, branded asset 606 incorporates the indicated teal color into the cap and the bottle label of a drink bottle. As another example, branded asset 602 incorporates the indicated white color onto a background of a shoulder pad. The asset branding platform may also incorporate the USPTO logo from the image file into various objects. As an example, branded asset 604 displays the USPTO logo on the front of an asset representing a barrel. In an example, incorporating a logo into a branded asset can include mapping the image onto the surface of an object. This can distort the image such that it appears along a non-planar surface. As an example, branded asset 602 illustrates an example where the logo is incorporated along a curved surface (e.g., of a shoulder pad) that is tilted. Mapping the image onto an asset can involve mapping the logo onto a texture file of an asset. The asset branding platform may incorporate the logo into the texture file (e.g., unbranded asset) of an object by projecting the image onto the object's geometry, which can distort the image so that it appears along the surface of the object. In an example, objects may be programmed to move. For example, objects may be animated within an electronic environment. In this example, the logo may move along with the object as part of its texture file.

Referring to FIG. 6B, illustrated is an example of how logos can move with the objects they are incorporated into. As objects move, their assets (e.g., texture files) may be updated to maintain alignment with the objects'new position. FIG. 6B illustrates an example where a viewpoint that the branded assets of FIG. 6A are observed from has changed. The viewpoint has been rotated such that the branded assets 600 are viewed from a different angle. The logos incorporated into assets may move along with the objects. For example, as the object of the branded asset 602 has rotated along with the asset, such that slightly more of the USPTO logo is visible. While FIG. 6B displays a relatively simple change of viewpoint, this may also apply to more complex object movements within an electronic environment. For example, as an object executes animated movements, the branded assets 600 may change according to those movements. Specifically, a spatial configuration (e.g., position, orientation, perspective, and/or the like) of a logo incorporated into the branded asset can change. For example, as the character to which the branded asset 602 is attached executes movements, such as fighting or running, the spatial configuration of the logo may update in real time to reflect the character's motion, ensuring that the logo remains visually consistent with the animated behavior of the object. The updates can be determined based on a mapping of a texture file to the object's geometry. The predicted branded assets 600 generated by the asset branding platform therefore represent an image output of an artificial intelligence model (e.g., model 112 of FIG. 1) that can be mapped to an object's geometry as a texture file for dynamic integration into an electronic environment.

Referring to FIG. 6C, illustrated is an example of how indicating different colors in the request can affect how the branded assets 600 are generated. The branded assets 600 are generated by the asset branding platform based on a request including an image file representing the USPTO logo and an indicated red color (e.g., represented by the striped pattern slanted from top left to bottom right such as shown by branded asset 606) and yellow color (e.g., represented by the striped pattern slanted from top right to bottom left such as shown by branded asset 602), in place of teal and white. Based on this request, the asset branding platform (e.g., model 112 of the asset branding platform 102 of FIG. 1), can generate branded assets 600 that display red and yellow elements, along with the USPTO elements. As an example, the branded asset 602 displays a yellow background, instead of the white background displayed in FIG. 6A and FIG. 6B. As another example, branded asset 606 displays a red cap and a red label background, instead of the teal cap and label background displayed in FIG. 6A and FIG. 6B.

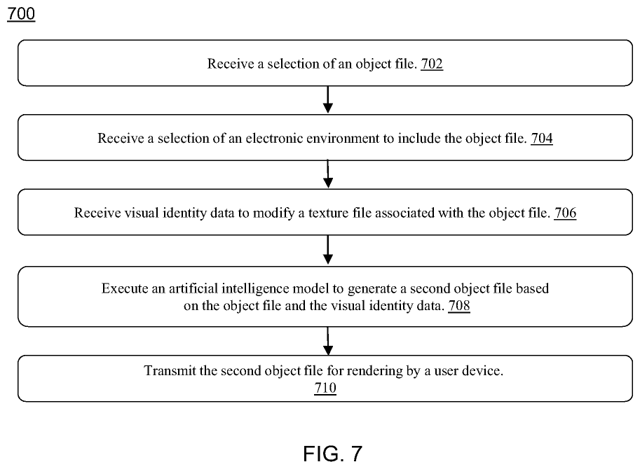

FIG. 7 illustrates a flow diagram of a method for generating branded assets, according to an embodiment. The method 700 may include steps 702-710. However, other embodiments may include additional or alternative steps or may omit one or more steps altogether. The method 700 is described as being executed by an asset branding platform (e.g., a computer similar to the asset branding platform 102). However, one or more steps of the method 700 may be executed by any number of computing devices operating in the system described in FIG. 1 (e.g., the implementation system 104, request system 122, and/or demographics system 118.

The branded objects generated by the methods and systems discussed herein can be implemented in various electronic environments, such as video games, virtual reality spaces, or social media platforms. Using the method discussed in FIG. 7, a processor (e.g., the asset branding platform) can generate a branded object based at least on visual identity data and a style vector associated with an environment style of the electronic environment. For example, the asset branding platform can use the AI model (e.g., one or more AI models) discussed herein to generate an object that incorporates visual aspects of the visual identity data and aligns with the environment style of the electronic environment. In an example, the asset branding platform can generate a new texture file that includes visual aspects of the visual identity data that have been modified to align with the environment style. Using the AI models discussed herein, instead of conventional methods, allows for rapid generation of branded objects that consistently maintain critical identity features of the visual identity data while aligning the incorporated visual identity data with an environment style. By conditioning the AI model on different styles, the asset branding platform can generate branded objects that are suitable for a wide range of electronic environments. As a result of the methods and systems described herein, the asset branding platform may generate branded objects in a broad range of environment styles with high fidelity to maintain crucial aspects of visual identity data, resulting in a more efficient pipeline from a request to generate the branded object to deployment of the branded object in the electronic environment.

In some embodiments, the asset branding platform may receive a request to render a second object file. For example, the asset branding platform may receive a request from a device (e.g., such as the request system 122 of FIG. 1) to generate a second object file incorporating visual identity data that is to be deployed (e.g., rendered) in an electronic environment. As described herein, the asset branding platform may generate a second object file including a new texture file generated by the AI model based on selections indicated by the request. The second object file may be transmitted to an implementation system (e.g., the implementation system 104 of FIG. 1) to be deployed. In some examples, the texture file may correspond to a mesh. The mesh may define a geometric structure of the object. For example, the mesh may include a plurality of interconnected geometric elements (e.g., vertices, edges, and/or polygons) that represent a shape and surface of the object. The vertices of the mesh may define discrete spatial positions in three-dimensional space, and the edges and polygons connecting the vertices may define the surface topology of the object. Movement of the object during rendering may be defined by transformations and/or deformations applied to the mesh. For example, transformations such as translation, rotation, and/or scaling may reposition the mesh within the electronic environment, while deformations such as skeletal animation and/or morph targets may alter the relative positions of the vertices to simulate articulated movement. In some examples, points of the texture file may map to points on the mesh via texture coordinates. For example, each point and/or region of the texture file may be associated with a corresponding surface location of the mesh based on a texture-to-mesh mapping. The texture-to-mesh mapping may assign a pair of texture coordinates (e.g., UV coordinates) to each vertex of the mesh, where a first coordinate value (e.g., a U value) corresponds to a horizontal position within the texture file and a second coordinate value (e.g., a V value) corresponds to a vertical position within the texture file. Regions of the texture file that fall between mapped vertices may be interpolated across the corresponding polygon of the mesh during rendering so that the texture file appears continuous across the surface of the object. Based on the transformations and/or deformations applied to the mesh, the mapped points of the texture file may move, deform, and/or reorient in accordance with the mesh during rendering of the object. For example, when a vertex of the mesh is displaced by a skeletal animation operation, the texture coordinate associated with the vertex may follow the displacement, and the corresponding region of the texture file may be rendered at the new position of the vertex. As a result, visual elements incorporated into the texture file, such as logos and/or colors from visual identity data, may remain affixed to the surface of the object as the object moves within the electronic environment. As an example, an asset representing a shoulder pad (e.g., the character 602 of FIG. 6A) may be associated with a mesh that defines a geometric structure and surface of the shoulder pad. Based on the mesh, a plurality of vertices representing surface locations of the shoulder pad may be defined, and each vertex may be assigned texture coordinates that map to a corresponding region of the texture file. Based on transformations applied to the mesh during rendering, the vertices may move relative to one another to define movement of the shoulder pad. The texture file representing an appearance of the shoulder pad may be rendered at each frame according to the current positions of the vertices and the associated texture coordinates, such that the texture file moves, deforms, and/or reorients in accordance with the mesh during rendering.

At step 702, the asset branding platform may receive a selection of an object file. For example, the asset branding platform may receive an indication of an object file corresponding to an object that is rendered within an electronic environment in accordance with a texture file as part of the request to generate the second object file. The object file may be compiled code that defines properties of an object (e.g., item, character, and/or the like) in the electronic environment. In some examples, the object file may include one or more assets, such as the texture file, that define properties of the object within the electronic environment. For example, the texture file may define the appearance of the object within the electronic environment. In some examples, the asset branding platform may retrieve the texture file of the object file based on the selection. For example, the asset branding platform may retrieve the texture file from an internal database (e.g., default asset data storage 106 of FIG. 1). In some examples, the selection of the object file may be determined based on another aspect of the request to generate the second object file. For example, the selection of the object file may be determined based on an electronic environment indicated by the request. In this example, the asset branding platform may select the object file from a set of object files associated with the electronic environment. As an example, the asset branding platform may select an award object file representing an award given (e.g., displayed) to users of the electronic environment based on game logic based on the electronic environment indicated by the request. As described herein, a new texture file may be generated for the award (e.g., award object file) based at least on the visual identity data and environment style.

At step 704, the asset branding platform may receive a selection of an electronic environment to include the object file. For example, the asset branding platform may receive a selection of an electronic environment to deploy the second object file in as part of the request to generate the second object file. In an example, the selection of an electronic environment may include and/or be associated with a style code identifying an environment style of the electronic environment. The style code may be associated with a style vector defining features (e.g., resolution, saturation, theme and/or the like). In an example, the selection of an electronic environment may include the style vector indicating one or more features for the second object file to be generated based on. In this example, the included style vector may be a modified version of a standard style vector for the environment style, where one or more components corresponding to features of the environment style have been modified. In some examples, the selection of the electronic environment may be determined based on the object file included in the request. For example, the asset branding platform may identify the selection of the electronic environment based on determining that the object file received in the request is associated with the electronic environment.

In some embodiments, the selection of an electronic environment may be based on a compatibility score. For example, a demographics system (e.g., the demographics system 118 of FIG. 1) may compare a first set of user attributes (e.g., demographics such as age, sex, race, income, and/or the like) associated with the electronic environment to a second set of user attributes associated with an organization represented by the visual identity data (e.g., a brand associated with visual identity data such as a logo). In some examples, the demographics system may recommend the electronic environment based on a compatibility score satisfying a compatibility threshold. The compatibility score may be a numerical representation of the overlap between the first set of user attributes and the second set of user attributes.

In some embodiments, the request to generate the second object file may include deployment guidelines. For example, the request may include timeframe (e.g., a start date and an end date) for deploying the second object file in the electronic environment. In some examples, the deployment guidelines may indicate a target set of user attributes. In these examples, the asset branding platform may transmit the second object file to be deployed in individual executions of the electronic environment based on the target set of user attributes. As an example, the asset branding platform may transmit the second object file to the electronic environment of a user based on identifying a match between the target set of user attributes and a set of user attributes associated with the user. In some examples, the asset branding platform may deploy the second object file in executions of a plurality of electronic environments based on identifying a match between users associated with the executions and the target set of user attributes.

At step 706, the asset branding platform may receive visual identity data. For example, the asset branding platform may receive visual identity data including files (e.g., images, color specifications, and/or the like) that can be used to modify a texture file. The texture file may represent an asset of the object file that establishes the appearance of the associated object in the electronic environment. In some examples, the asset branding platform may receive the visual identity data as part of the request to generate the second object file. In these examples, the second object file may appear to include the visual attribute of the visual identity data when rendered within the electronic environment.

In some embodiments, the visual identity data may include a mask. For example, the visual identity data may include a mask around an important portion of the visual identity data. The mask may isolate the important portion of the image during generation of the second object file. The important portion may be a portion of an image included in the visual identity data that that is significant to recognition of a visual identity associated with the visual identity data (e.g., logo). In an example, the mask may prevent distortion of the logo in the second object file. In some examples, the visual identity data may include color constraints. For example, the visual identity data may include color constraints on colors that are significant to recognition of the visual identity. The color constraints may define an acceptable variance between colors in the visual identity data and colors in the second object file. In an example, the color constraints may define an acceptable level of variance between a color histogram associated with the visual identity data and a color histogram associated with the second object file. Additionally or alternatively, the color constraints may a pixel-level constraint between pixels in the visual identity data and corresponding pixels in the second object file. In some examples, the color constraints may be applied to a portion of the visual identity data, such as the mask. For example, the color constraints may be a pixel-wise constraint applied to the mask of the visual identity data.

At step 708, the asset branding platform may execute an artificial intelligence (AI) model to generate the second object file. For example, the AI model may be configured to ingest visual attributes associated with the electronic environment (e.g., the style vector) and/or visual identity data and predict a second texture file (e.g., branded asset 306 of FIG. 3) based on the first texture file (e.g., default asset 302 of FIG. 3) of the object file. In some examples, the AI model may predict the second texture file based on the visual identity data (e.g., visual identity data 304 of FIG. 3). For example, the AI model may incorporate at least part of the visual identity data into the visual appearance of the second texture file. As an example, the AI model may generate a version of the first texture file of the object file that incorporates a logo included in the visual identity data. As another example, the AI model may generate a version of the first texture file of the object file that incorporates a color included in the visual identity data. In some examples, the AI model may predict a modification to the visual identity data that is incorporated into the second texture file. For example, the AI model may predict the modification to the visual identity data based on the visual attributes associated with the electronic environment. As an example, the AI model may adjust an aspect of a color (e.g., saturation, brightness, temperature, and/or the like) from the visual identity data. As another example, elements of an image (e.g., image of a mascot, logo, and/or the like) included in the visual identity data may be added and/or removed to fit a theme (e.g., realistic, steampunk, futuristic, and/or the like) included in the visual attributes associated with the electronic environment. In some examples, the second object file may include the second texture file. For example, the second object file may be a version of the first object file that includes the second texture file in place of the texture file (e.g., original texture file). In this example, the object associated with the second object file may be behave in the electronic environment in the same or similar manner as the object associated with the first object file, however, may appear differently.

In some embodiments, the object associated with the object file may be displayed as an animation and the modification to the object file may be predicted for each frame of the animation. For example, the texture file may include a plurality of frames that each represent a different perspective of the object. As an example, the object may be a coin that is displayed as an animation of a spinning coin. In this example, the animation may include multiple frames that depict the coin at various rotational angles, which can create the illusion of the coin continuously spinning when played in a sequence. In some examples, the modification may be predicted for each frame of the animation. For example, the artificial intelligence model may generate a modification for each frame. In this example, the artificial intelligence model may be trained to generate modifications that preserve common features at key points of the object, which can help ensure a cohesive transition across the sequence of frames. In an example, the texture file may be a sprite sheet that includes multiple small images (e.g., frames) arranged in a grid format. In this example, the modification may be predicted for each of the small images in the sprite sheet.

In some embodiments, the modification may include a filter that is overlayed on the object file. For example, the artificial intelligence model may generate a filter that can modify a texture file, such as the texture file of the object file. In an example, the filter may change the colors in a texture file. For example, the filter may adjust the shade (e.g., saturation, contrast, and/or the like) of colors within the texture file or map certain colors to a different color. Additionally, or alternatively, the filter may add elements, such as a logo from the visual identity data to the texture file. The filter may be tailored or adjusted to the object file. For example, the filter may add a logo to a specific position within the texture file based on a prediction of the artificial intelligence model. In some examples, the filter may be applied to the object file and the second object file may represent an updated version of the object file. For example, the asset branding platform may apply the filter generated by the artificial intelligence model to the object file to generate the second object file. In this example, the asset branding platform may store the filter and/or modified texture file. For example, transmitting the second object file for rendering by a user device can include transmitting a file including the filter and/or the object file. In this example, the user device may render the second object file by applying the filter to the texture file of the object file. The filter may be applied according to logic (e.g., in the logic data storage 116 of FIG. 1) associated with the filter. For example, the filter may be applied for a predefined period of time specified by the logic. At the end of this time period, the filter may be removed. Alternatively, transmitting the second object file for rendering can include transmitting just the modified texture file. In this example, the modified texture file may replace the texture file for a period of time defined according to logic associated with the modified texture file.

In some embodiments, the AI model may generate the second object file based on modifying the visual identity data to conform to an environment style. For example, the AI model may predict a modification to the visual identity data that makes it more visually consistent with the environment style. As an example, the AI model may modify the colors (e.g., hue, saturation, and/or the like) included in the visual identity data. As another example, the AI model may adjust the art style (e.g., realistic, cartoonish, and/or the like). For example, the AI model may adjust a three-dimensional item in the visual identity data to appear two-dimensional (e.g., by adjusting perspective, shading, and/or the like). This may result in visual identity data that appears more visually consistent with the electronic environment. In some examples, the AI model may modify the visual identity data based on a style vector. The style vector may include one or more numerical representations of the environment style. In an example, the style vector may be generated based on embedding features of a reference image to generate numerical representations of the features. In this example, the AI model may modify the visual identity data based on numerical representations of features of a reference image that represents the electronic environment.

In some embodiments, the AI model may generate the second object file based on modifying a resolution of the visual identity data (e.g., at least part of the visual identity data). For example, the resolution of the visual identity data may be modified to appear visually consistent with the electronic environment. The visual identity data may be associated with a first resolution and the visual attributes associated with the electronic environment may indicate a second resolution (e.g., 1280×720). In an example, the visual identity data may be resampled to reduce the resolution, and as a result the number of pixels in the visual identity data may be reduced. In another example, the visual identity data may be resampled to increase the resolution, and as a result the number of pixels in the visual identity data may be increased. In this example, the AI model may predict the added pixels to increase the first resolution of the visual identity data. In some examples, the AI model may predict a degree of resampling that will result in the visual identity data appearing visually consistent (e.g., in terms of resolution) with the electronic environment. In an example, the visual identity data may be incorporated as a part of the second texture file. In this example, modifying the visual identity data to numerically match the second resolution or a resolution associated with the texture file may not result in visual identity data that looks consistent with the electronic environment. While conventional methods of modifying the resolution of visual identity data to look visually consistent with the electronic environment may include resizing the visual identity data and determining if it looks visually consistent with the electronic environment based on subjective judgement, the recited systems and methods provide a consistent, the described systems and methods provide a consistent process for predicting a modification to the resolution of the visual identity data.

In some embodiments, the AI model may be trained using a generative adversarial network (GAN) network. For example, the AI model may be trained using a GAN network including a generator configured to predict generated texture files and a discriminator model configured to discriminate between generated texture files (e.g., generated asset 206 of FIG. 2) predicted by the generator model and stylized (e.g., ideal) texture files (e.g., stylized asset 214 of FIG. 2) in a training data set. In this example, the trained generator model may be the AI model. In some examples, the AI model may be trained using a GAN network that is conditioned based on environment styles. For example, the generator model and/or discriminator model of the GAN network may receive a style code. In this example, the style code may be associated with a style vector including numerical representations of features of the electronic environment. In some examples, the generator model may predict the generated texture file based on the style code. In some examples, the discriminator model may discriminate between generated texture files and stylized texture files based on the style code. For example, the discriminator model may identify that a given texture file is generated by the generator model based on the given texture file not complying with the features described in the style vector.

In some embodiments, the AI model may be trained based on discriminating between generated texture files and stylized (e.g., ideal) texture files. For example, the GAN network may receive a training data set including training visual identity data, an environment style (e.g., style code, style vector, and/or the like), and/or first training asset (e.g., stylized texture file). The first training asset may be an asset that is not generated by the generator model. For example, the first training asset may be an ideal version of the stylized texture file that is not generated by an artificial intelligence model. In this example, the first training asset may be generated by a person. In an example, the generator model may generate a second training asset (e.g., generated texture file) based on the training visual identity data and/or the environment style. In some examples, the second training asset may be generated based on a third training asset representing a default texture file, where the third training asset is included in the training data set. In this example, the second training asset (e.g., stylized asset) may be a modified version of the third training asset. The second training asset may be modified based on visual identity data. In some examples, the discriminator model may determine whether the second training asset is the second training asset generated by the model or the first training asset representing a stylized asset. The discriminator model may generate first output indicating whether the second training asset is generated by the generator model. For example, based on detecting feature deviations (e.g., deviations from real-world geometry such as implausible configurations of anatomy, deviations from the environment style, deviations from the visual identity data, and/or the like) the discriminator model may determine that the second training asset is generated by an artificial intelligence model (e.g., the generator model). The discriminator model may generate second output indicating whether the first training asset is generated by the generator model. For example, based on failing to detect deviations, the discriminator model may determine that the first training asset is not generated by artificial intelligence model (e.g., the generator model). In some examples, the parameters (e.g., weights) of the generator model and/or discriminator model may be adjusted based on the determination. The system may determine a loss based on the first output and/or the second output. The loss may be determined based on whether the first training asset and/or the second training asset were correctly identified. For example, the loss may be an adversarial loss associated with identification, by the discriminator model, of generated training assets and training assets not generated by the generator model. In response, a correct determination that the second training asset is generated by the generator model, the weights of the generator model may be adjusted to generate output that is a closer match to the first training asset and/or more difficult for the discriminator model to identify. Similarly, the weights of the discriminator model may be adjusted to identify between the first training asset and the second training asset more accurately. In some examples, the AI model may be trained based on an iterative process, where the weights of the discriminator and/or generator are adjusted at each iteration. In this example, the training data set may include a plurality of training sets including visual identity data, an environment style, a first training asset, and/or a third training asset.

In some embodiments, the asset branding platform may train the AI model using one or more types of loss. For example, the asset branding platform may determine a loss between the second training asset generated by the generator model and the first training asset (e.g., stylized texture file) in the training data set. As another example, the asset branding platform train the AI model (e.g., generator model) using adversarial loss. Adversarial loss may be based on the accuracy of the discriminator model. For example, the parameters of the generator model may be updated to produce images that are closer to the first training asset. As another example, the parameters of the discriminator model may be updated to more accurately discriminate between the first training asset and the second training asset.

In some examples, the AI model (e.g., generator) may be updated based on content preservation loss during training. Content preservation loss may be based on distortion of an area of the training visual identity data that is associated with a mask in the second training asset. For example, a loss may be determined between the mask and a corresponding generated region of the second training asset (e.g., generated texture file). As an example, the mask may include a logo, and the corresponding generated region of the second training asset may be a portion of the second training asset that includes the logo. In an example, the content preservation loss may be a pixel-wise loss. For example, the content preservation loss may be an L1 or L2 pixel-wise loss between the original region and the generated region. In another example, the content preservation loss may be a feature-based loss. For example, the content preservation loss may be calculated by a visual geometry group (VGG) model. In this example, the VGG model may calculate a perceptual loss between the mask and the corresponding region of the second training asset as the feature-based loss. The VGG model may identify features in the mask and the second training asset by using convolutional layers with small filters to capture fine details and patterns and then determine a difference between the features as the perceptual loss. In described examples, the content preservation loss may indicate how much the mask (e.g., logo) has been distorted in the second asset. The generator model may be updated to generate objects that minimize this distortion. In an example, the content preservation loss may be a combination (e.g., weighted or unweighted) of pixel-based loss and feature-based loss. In some examples, the generator model may be updated based on color consistency loss. Color consistency loss may be based on distortion of colors associated with the training visual identity data. For example, colors of the second asset may be adjusted based on the environment style. As an example, the saturation of an image may be increased to better fit with the environment style. In an example, the color consistency loss may be determined based on comparing colors of the mask and colors of the second training asset (e.g., a portion of the second training asset corresponding to the mask or the entire second training asset). The color consistency loss may be determined based on color histogram matching (e.g., how closely the color histogram of the second training asset matches the mask) or direct pixel-level comparison. In an example, colors of the mask may be associated with an acceptable level of variance. In this example, color consistency loss may be determined based on whether the colors of the area in the second training asset corresponding to the mask are within the acceptable level of variance of the colors of the mask (e.g., either pixel-wise or color histogram). In some examples, the generator model may be updated based on a combination (e.g., weighted or unweighted) of adversarial loss, content preservation loss, and/or color consistency loss. As a result, the AI model may be trained to maintain significant portions of visual identity data, such as logos and colors, while modifying the visual identity data to appear visually consistent with the electronic environment.

At step 710, the asset branding platform may transmit the second object file for rendering by a user device. For example, the asset branding platform may transmit the second object file including the second texture file that has been generated based on visual attributes associated with the electronic environment and the visual identity data to an implementation system (e.g., such as the implementation system 104 of FIG. 1) for rendering by a user device. In an example, the asset branding platform may transmit the second texture file with an indication of the object file. In this example, the implementation system may deploy the second object file based on replacing the texture file of the object file with the second texture file. For example, the implementation system may replace the object file with the second object file or add the second object file as a new object file to an internal database. In some examples, the asset branding platform may transmit the second object file based on the second object file passing a review. For example, the second object file may be reviewed (e.g., by a person and/or model) and transmitted based on satisfying one or more quality metrics. The quality metrics may be associated with the second object file aligning with the environment style and/or the visual identity data. In some examples, the second object file may be deployed according to logic rules associated with the object file. In some examples, the asset branding platform may transmit the second object file with logic rules defining conditions for deployment. For example, the logic rules may define a start time and an end time for possible deployment of the second object file. In some examples, the second object file may be rendered by the user device based on deployment by the implementation system. For example, the second object file may be rendered by the user device as part of the electronic environment based on the implementation system deploying the second object file. In some examples, the implementation system may deploy the second object file based on the associated logic rules. For example, the system may deploy second object file based on the electronic environment satisfying certain conditions. As an example, the object file may be a trophy and the second object file may be a modified version of the trophy that displays a brand logo and/or brand colors (e.g., visual identity data). The second object file may be transmitted to the implementation system for deployment. In this example, the object file may be deployed when a user associated with the user device meets a certain metric within the electronic environment. In an example, the second object file may be deployed in place of the first object file when the user meets the certain metric within a start time and end time (e.g., campaign timeframe) associated with the second object file. Based on being deployed, the second object file may be rendered by the user device and may appear in the electronic environment.

In some embodiments, rendering the second object file may include rendering the second object file according to changes of the geometric structure of the mesh. For example, the second object file may move within the electronic environment. The movement of the second object file may be determined according to the geometric structure of the mesh. The electronic environment may simulate movement of the second object by applying transformations to points of the mesh. The second texture file may be rendered based on a mapping between the second texture file and the points. For example, regions of the second texture file may be mapped to corresponding points or surface regions of the mesh such that each region of the texture file is associated with a location on the mesh.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of this disclosure or the claims.

Embodiments implemented in computer software may be implemented in software, firmware, middleware, microcode, hardware description languages, or any combination thereof. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

The actual software code or specialized control hardware used to implement these systems and methods is not limiting of the claimed features or this disclosure. Thus, the operation and behavior of the systems and methods were described without reference to the specific software code being understood that software and control hardware can be designed to implement the systems and methods based on the description herein.

When implemented in software, the functions may be stored as one or more instructions or code on a non-transitory computer-readable or processor-readable storage medium. The steps of a method or algorithm disclosed herein may be embodied in a processor-executable software module, which may reside on a computer-readable or processor-readable storage medium. A non-transitory computer-readable or processor-readable media includes both computer storage media and tangible storage media that facilitate transfer of a computer program from one place to another. A non-transitory processor-readable storage media may be any available media that may be accessed by a computer. By way of example, and not limitation, such non-transitory processor-readable media may comprise RAM, ROM, EEPROM, CD-ROM or other optical disk storage, magnetic disk storage or other magnetic storage devices, or any other tangible storage medium that may be used to store desired program code in the form of instructions or data structures and that may be accessed by a computer or processor. Disk and disc, as used herein, include compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and/or instructions on a non-transitory processor-readable medium and/or computer-readable medium, which may be incorporated into a computer program product.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What we claim is:

1. A method comprising:
receiving, by a processor, a selection of an object file corresponding to an object to be rendered within an electronic environment in accordance with a texture file that corresponds to a mesh defining a geometric structure of the object;
receiving, by the processor, a selection of the electronic environment to include the object file;
receiving, by the processor, visual identity data to modify the texture file associated with the object file to generate a second object file, such that a rendering of the second object file within the electronic environment includes a visual attribute of the visual identity data;
executing, by the processor, an artificial intelligence model to generate the second object file based on the object file and the visual identity data, wherein the artificial intelligence model is configured to ingest visual attributes associated with the electronic environment and the visual identity data and predict a modification to the texture file of the object file to generate a second texture file; and
transmitting, by the processor, the second object file for rendering by a user device as a part of rendering the electronic environment, wherein rendering the second object file comprises rendering the second texture file according to changes of the geometric structure of the mesh.

2. The method of claim 1, wherein the artificial intelligence model is trained using a generative adversarial network (GAN) network comprising a generator model and a discriminator model.

3. The method of claim 1, wherein the artificial intelligence model is trained using at least one of adversarial loss, content preservation loss, and color consistency loss.

4. The method of claim 2, wherein the artificial intelligence model is trained with a training data set comprising training visual identity data, an environment style, and a first training asset that is not generated by the generator model, by a process comprising:
generating, by the generator model, a second training asset based on the training visual identity data and the environment style;
determining, by the discriminator model, a first output indicating whether the second training asset is generated by the generator model;
determining, by the discriminator model, a second output indicating whether the first training asset is generated by the generator model; and
adjusting at least one weight of the generator model based on a loss determined based on from the first output and the second output.

5. The method of claim 1, wherein the artificial intelligence model generates the second object file based on modifying a first resolution of the visual identity data based on a second resolution of the object file.

6. The method of claim 1, wherein the artificial intelligence model generates the second object file based on modifying one or more visual elements of the visual identity data to conform to an environment style associated with the electronic environment.

7. The method of claim 1, further comprising:
identifying, by the processor, a compatibility score based on a first set of user attributes associated with the electronic environment and a second set of user attributes associated with an organization represented by the visual identity data; and
recommending, by the processor, the electronic environment based on the compatibility score satisfying a compatibility threshold.

8. The method of claim 1, wherein the visual identity data comprises a mask indicating a portion of the visual identity data that is to be minimally modified.

9. The method of claim 1, wherein the texture file comprises a plurality of frames each representing a perspective of the object and the modification to the object file is predicted for each frame.

10. The method of claim 1, wherein the modification comprises a filter that is overlayed on the texture file and generating the second object file comprises applying the filter to the object file.

11. A computer system comprising a computer-readable medium storage comprising a set of non-transitory instructions, that when executed, cause a processor to:
receive a selection of an object file corresponding to an object to be rendered within an electronic environment in accordance with a texture file that corresponds to a mesh defining a geometric structure of the object;
receive a selection of the electronic environment to include the object file;
receive visual identity data to modify the texture file associated with the object file to generate a second object file, such that a rendering of the second object file within the electronic environment includes a visual attribute of the visual identity data;
execute an artificial intelligence model to generate the second object file based on the object file and the visual identity data, wherein the artificial intelligence model is configured to ingest visual attributes associated with the electronic environment and the visual identity data and predict a modification to the texture file of the object file to generate a second texture file; and
transmit the second object file for rendering by a user device as a part of rendering the electronic environment, wherein rendering the second object file comprises rendering the second texture file according to changes of the geometric structure of the mesh.

12. The computer system of claim 11, wherein the artificial intelligence model is trained using a generative adversarial network (GAN) network comprising a generator model and a discriminator model.

13. The computer system of claim 11, wherein the artificial intelligence model is trained using at least one of adversarial loss, content preservation loss, and color consistency loss.

14. The computer system of claim 12, wherein the GAN network is configured to train the artificial intelligence model with a training data set comprising training visual identity data, an environment style, and a first training asset by a process comprising:
generating, by the generator model, a second training asset based on the training visual identity data and the environment style;
determining, by the discriminator model in the GAN network, a first output indicating whether the second training asset is generated by the generator model;
determining, by the discriminator model, a second output indicating whether the first training asset is generated by the generator model; and
adjusting at least one weight of the generator model based on a loss determined based on from the first output and the second output.

15. The computer system of claim 11, wherein the artificial intelligence model generates the second object file based on modifying a first resolution of the visual identity data based on a second resolution of the object file.

16. The computer system of claim 11, wherein the artificial intelligence model generates the second object file based on modifying one or more visual elements of the visual identity data to conform to an environment style associated with the electronic environment.

17. The computer system of claim 11, wherein the set of non-transitory instructions further cause the processor to:
identify a compatibility score based on a first set of user attributes associated with the electronic environment and a second set of user attributes associated with an organization represented by the visual identity data; and
recommend the electronic environment based on the compatibility score satisfying a compatibility threshold.

18. The computer system of claim 11, wherein the visual identity data comprises a mask indicating a portion of the visual identity data that is to be minimally modified.

19. The computer system of claim 11, wherein the texture file comprises a plurality of frames each representing a perspective of the object and the modification to the object file is predicted for each frame.

20. The computer system of claim 11, wherein the modification comprises a filter that is overlayed on the texture file and generating the second object file comprises applying the filter to the object file.
